(19) United States
(12) Patent Application Publication
(10) Pub. No.: US 2025/0373219 A1
(43) Pub. Date: Dec. 4, 2025

(54) METHODS FOR MAKING SURFACE ACOUSTIC WAVE (SAW) DEVICES INCLUDING A SUPERLATTICE

(71) Applicant: ATOMERA INCORPORATED, LOS GATOS, CA (US)

(72) Inventors: HIDEKI TAKEUCHI, SAN JOSE, CA (US); ROBERT J. MEARS, WELLESLEY, MA (US); MAREK HYTHA, BROOKLINE, MA (US)

(21) Appl. No.: 19/220,752

(22) Filed: May 28, 2025

Related U.S. Application Data
(60) Provisional application No. 63/652,874, filed on May 29, 2024.

(51) Int. Cl. H03H 3/08; H10D 62/815

(52) U.S. Cl. CPC H03H 3/08; H10D 62/8162

(57) ABSTRACT

A method for making an electronic device may include forming a semiconductor region comprising a semiconductor layer and at least one non-semiconductor monolayer constrained within a crystal lattice of the silicon layer. The method may also include forming a plurality of spaced apart alternating N-type and P-type regions within the semiconductor region, forming at least one electrode associated with the semiconductor region, and poling the semiconductor region to align a net electrical dipole moment thereof using the plurality of spaced apart alternating N-type and P-type regions. The poled region may include a superlattice.

### RELATED APPLICATIONS

This application claims the benefit of U.S. App. No. 63/652,874 filed May 29, 2024, which is hereby incorporated herein in its entirety by reference.

### TECHNICAL FIELD

The present disclosure generally relates to semiconductor devices, and, more particularly, to surface acoustic wave (SAW) devices and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making an electronic device may include forming a semiconductor region comprising a semiconductor layer and at least one non-semiconductor monolayer constrained within a crystal lattice of the semiconductor layer. The method may also include forming a plurality of spaced apart alternating N-type and P-type regions within the semiconductor region, forming at least one electrode associated with the semiconductor region, and poling the semiconductor region to align a net electrical dipole moment thereof using the plurality of spaced apart alternating N-type and P-type regions.

In some implementations, the method may further include forming an insulator between the poled region and the at least one electrode. In an example implementation, forming the at least one electrode may comprise forming a pair spaced apart interdigitated transducers (IDTs) defining a Surface Acoustic Wave (SAW) device. In some implementations, the electrical dipole moment may comprise a permanent electrical dipole moment. The semiconductor region may include intrinsic regions between adjacent N-type and P-type regions in an example implementation. By way of example, the N-type and P-type regions may each have a dopant concentration of at least 1×10¹⁷/cm³.

In accordance with one example, the semiconductor layer and at least one non-semiconductor monolayer therein may comprise a plurality of stacked groups of layers, with each group of layers comprising a plurality of stacked base semiconductor monolayers defining a base semiconductor portion, and a respective non-semiconductor monolayer constrained within a crystal lattice of adjacent base semiconductor portions. In other words, the poled region may comprise a superlattice. By way of example, the stacked base semiconductor monolayers may comprise silicon, and the non-semiconductor monolayers may comprise oxygen. In one example implementation, the method may further include forming radio frequency (RF) circuitry coupled to the at least one electrode.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIGS. 4 (a)-4 (b) are schematic atomic diagrams illustrating an example superlattice configuration with random and ordered non-semiconductor atom orientation.

FIG. 5a is a top view of a surface acoustic wave (SAW) device including a superlattice in accordance with an example embodiment.

FIG. 5b is a cross section of the SAW device of FIG. 5a taken along line A-A′.

FIG. 5c is a schematic diagram illustrating the superlattice structure with ordered oxygen atoms between P-type and N-type layers of the SAW device of FIG. 5a in greater detail.

FIG. 6 includes atomic diagrams illustrating alignment of oxygen atoms in a superlattice in different SAW device configurations, and associated plot.

FIG. 7a is a schematic diagram illustrating a DC bias configuration corresponding to FIG. 6.

FIG. 7b is a table including spacing and E-field values for P-type and N-type layers inside the SAW device of 5a in accordance with an example embodiment.

FIG. 8 is a schematic diagram of an example SAW apparatus incorporating the SAW device of FIG. 5a.

FIG. 9 is a graph of simulated doping profiles for the SAW device of FIG. 8.

FIG. 10 is a flow diagram illustrating a related method for making an electronic device.

FIG. 11 is a schematic cross-sectional diagram of a poled region of a SAW device in an example implementation.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers and that this thereby leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric Sio, at the Si—SiO₂ interface is known to exhibit inferior insulating properties relative to stoichiometric SiO₂. Reducing the amount of sub-stoichiometric SiOₓ at the interface may more effectively confine free carriers (electrons or holes) in the silicon, and thus improve the mobility of these carriers due to electric fields applied parallel to the interface, as is standard practice in field-effect-transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as will be discussed further below.

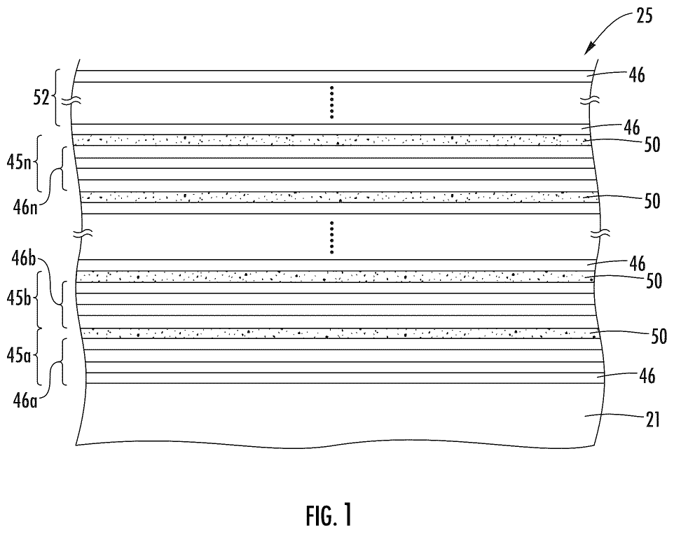

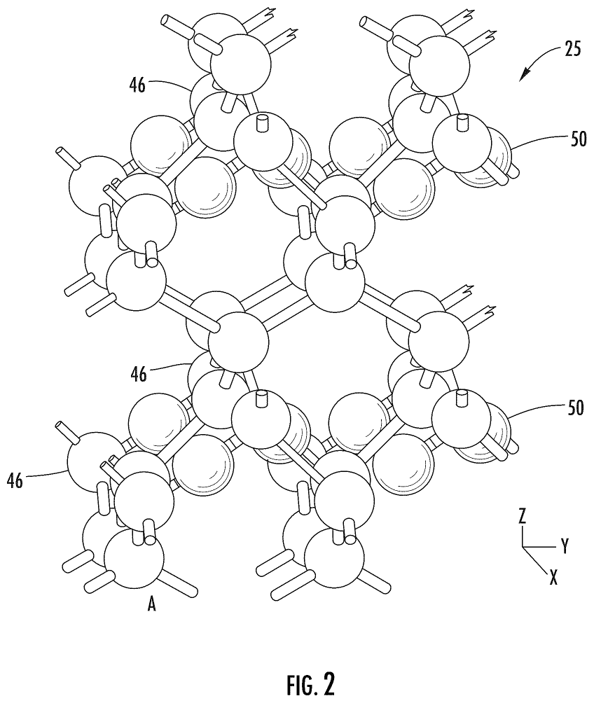

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that non-semiconductor monolayers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present embodiments, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the embodiments may be readily adopted and implemented, as will be appreciated by those skilled in the art.

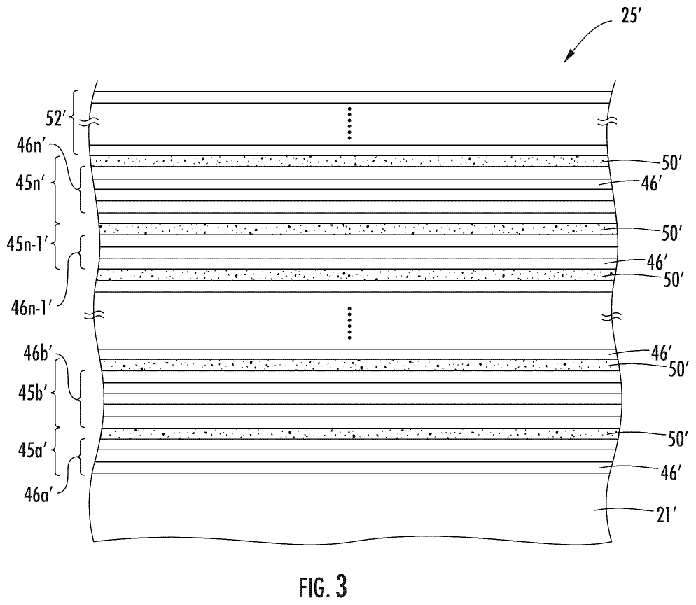

Referring now additionally to FIG. 3, another embodiment of a superlattice 25′ in accordance with the embodiments having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

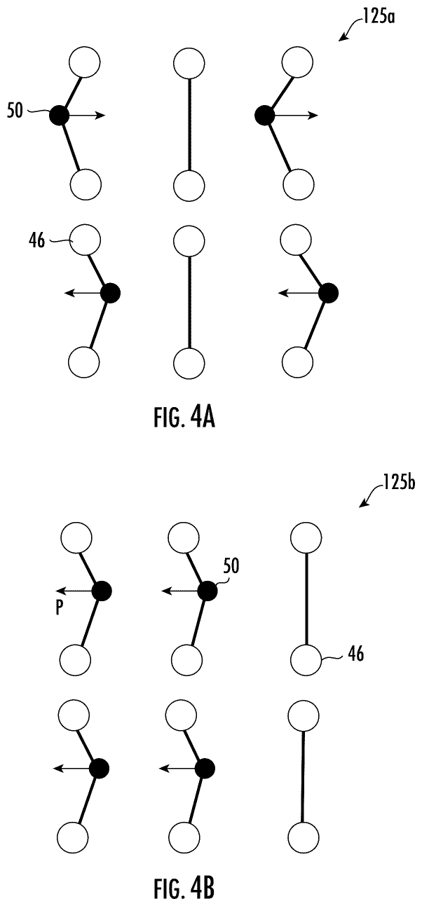

Turning to FIGS. 4 (a)-4 (b), as discussed in U.S. Pub. No. 2007/0161138, which is also from the present Applicant and is hereby incorporated herein in its entirety by reference, the above-described MST films may be configured to exhibit higher piezoelectricity with a higher electromechanical coupling coefficient k than other piezoelectric materials such as LiTaO₃, for example. In the case of an Si/O MST film, for example, piezoelectricity would require oxygen atoms in the MST film to be aligned in one direction. As illustrated in the diagram 125a of FIG. 4a, oxygen atoms 50 of a typical as-grown MST film will have a random orientation. However, as shown in FIG. 4b, the approach set forth herein provides device structures to align these oxygen atoms 50 after the MST film 125b growth to exhibit piezoelectricity.

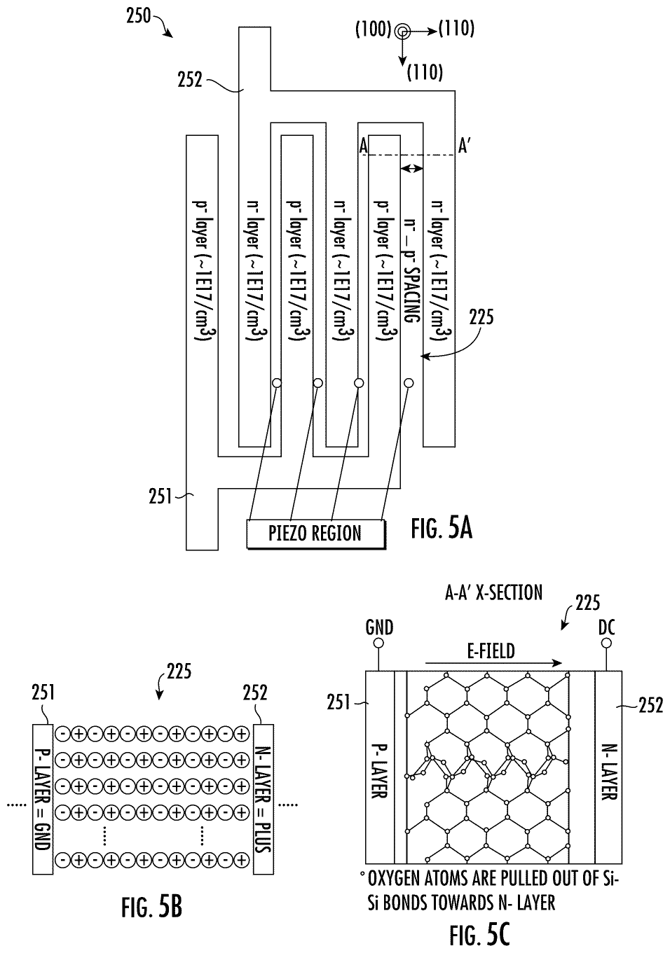

Referring additionally to FIGS. 5a-5c, an example surface acoustic wave (SAW) device 250 configuration may be fabricated by forming p-regions 251, intrinsic (MST) regions 225, and n-regions 252 inside the device region. More particularly, the P-type and N-type regions 251, 252 may be formed by photolithography and ion implantation to an intrinsic epitaxial Si film with an MST oxygen (or other non-semiconductor) layer 225, for example. A rapid thermal anneal (RTA) may be performed to activate the implanted dopants, followed by application of a direct current (DC) bias to the P-type and N-type layers 251, 252 after device fabrication. The electric field induced by the DC bias between P-type (GND) and N-type (positive bias) layers 251, 252 aligns randomly oriented oxygen (or other non-semiconductor) atoms of the as-grown MST film in the intrinsic region. The aligned oxygen atoms in the intrinsic region exhibit piezoelectricity enabling SAW (surface acoustic wave) functionality, as noted above.

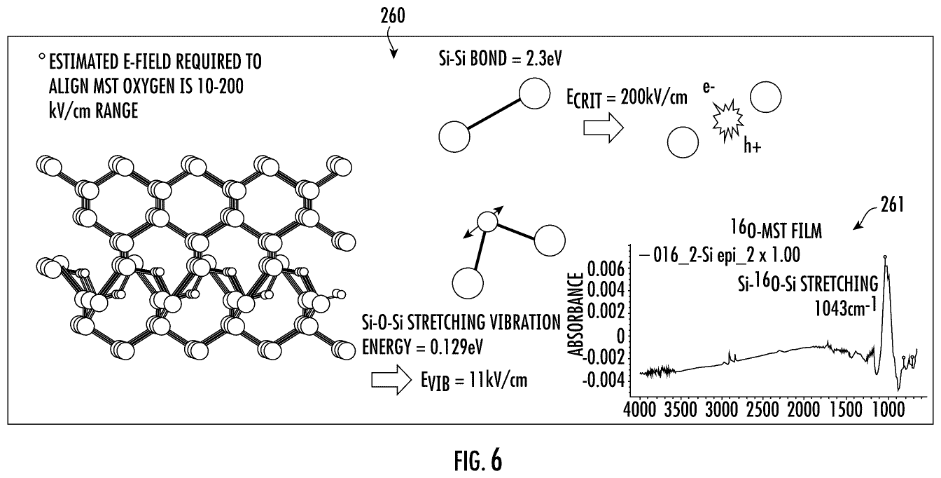

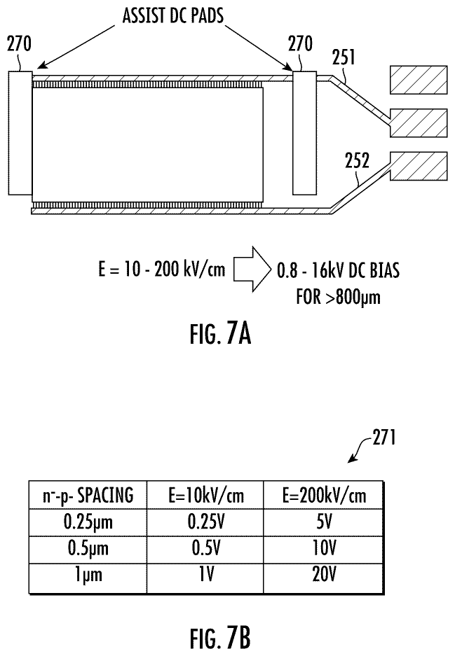

An example implementation utilizing a ¹⁶O-MST Si/O film is now described with respect to the atomic diagram 260 and chart 261 of FIG. 6. In the present example, an estimated E-field range for aligning MST oxygen atoms of 10-200 kV/cm is used. Si—Si bonds are broken at 200 kV/cm, and Si—O—Si vibration energy is equivalent to 10 kV/cm. The P-type and N-type layers may preferably be inside the device region to keep DC-bias within a practical range. By way of comparison, SAW device dimensions of greater than 100 um require a relatively high DC bias (e.g., 0.8-16 kV) when doping layers are formed outside the device. On the other hand, the required DC-bias is reduced to <20V when doping layers are formed inside the device. An example DC biasing configuration is shown in FIG. 7a which utilizes assist DC pads 270. Table 271 (FIG. 7b) provides example spacings for P-type and N-type layers 251, 252 and associated bias voltages for different E-fields.

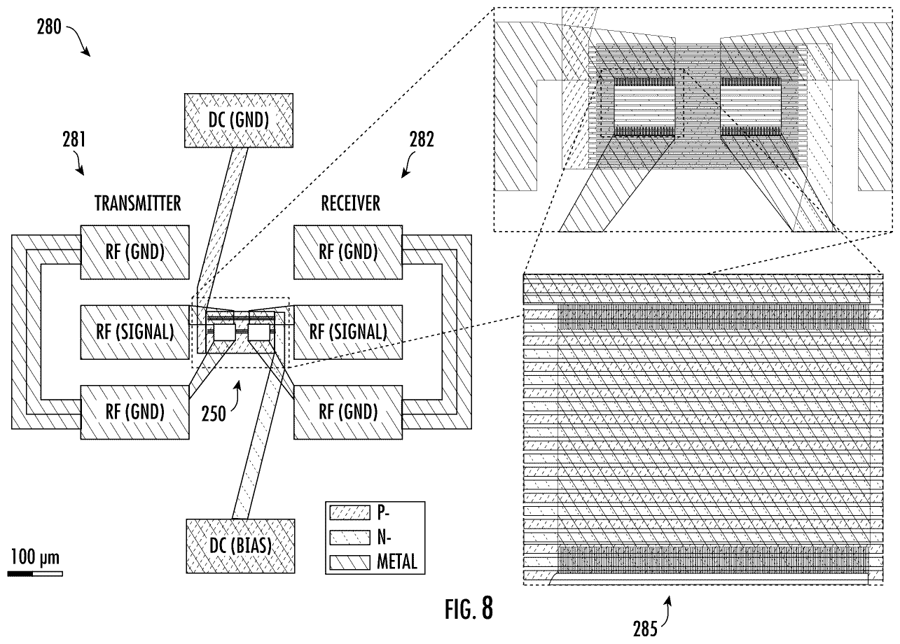

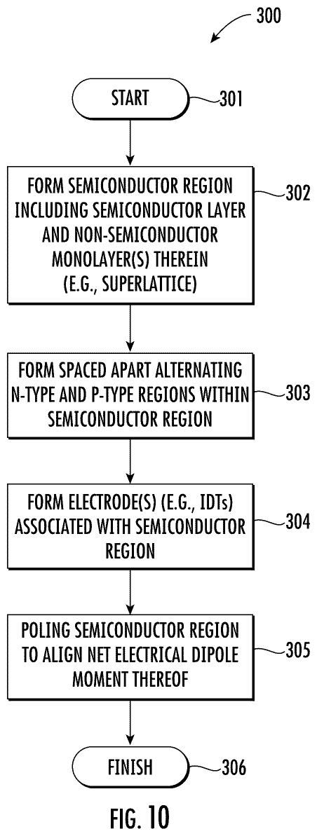

An example method for making the device 250 is now described with reference to the flow diagram 300 of FIG. 10. Beginning at Block 301, the method illustratively includes forming a semiconductor region comprising a semiconductor layer and at least one non-semiconductor monolayer therein, which in the example of FIG. 5A is the intrinsic epitaxial Si film with an MST oxygen layer 225 (Block 302). The method also includes forming the spaced apart alternating P-type and N-type regions 252, 252 within the semiconductor region, at Block 303, forming one or more electrodes (such as the interdigitated transducers (IDTs) 285 shown in FIG. 8) which are associated with the semiconductor region (Block 304), and poling the semiconductor region to align a net electrical dipole moment thereof (Block 305), as discussed further above. The method of FIG. 10 illustratively concludes at Block 306.

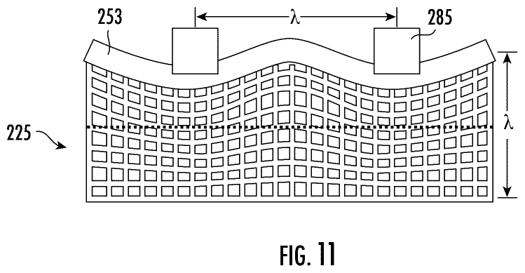

Referring additionally to FIG. 11, in some implementations it may be desirable to also incorporate an insulator (e.g., SiO2) between the RF electrodes (e.g., IDTs 285) and the piezoelectric region. By way of background, piezoelectric materials convert electrical energy from RF signals into strain energy. Free carriers in the piezoelectric material may lead to undesirable energy loss, resulting in a loss in piezoelectricity. Typical piezoelectric materials (e.g., AlN, PZT, etc.) are insulators, and thus free carriers are not an issue. However, metal electrodes in direct contact with silicon may inject free carriers into the material that could be undesirable in some implementations.

In the illustrated example, an insulator layer 253 (e.g., SiO₂ in the case of an Si/O poled region) is positioned between the piezoelectric or poled region and the electrodes (e.g., the IDTs 285 in the example of FIG. 8). By way of example, ˜20-50 nm of thermal oxide may be formed on top of piezoelectric MST substrate prior to metal electrode deposition. Oxide inserted underneath the metal electrodes helps prevent carrier injection into the semiconductor (here Si). Moreover, the insulator layer 253 may also advantageously serve as an etch stop layer for metal etching, as metal dry etching on Si can be challenging. In FIG. 11, λ represents the surface (Rayleigh) wave.

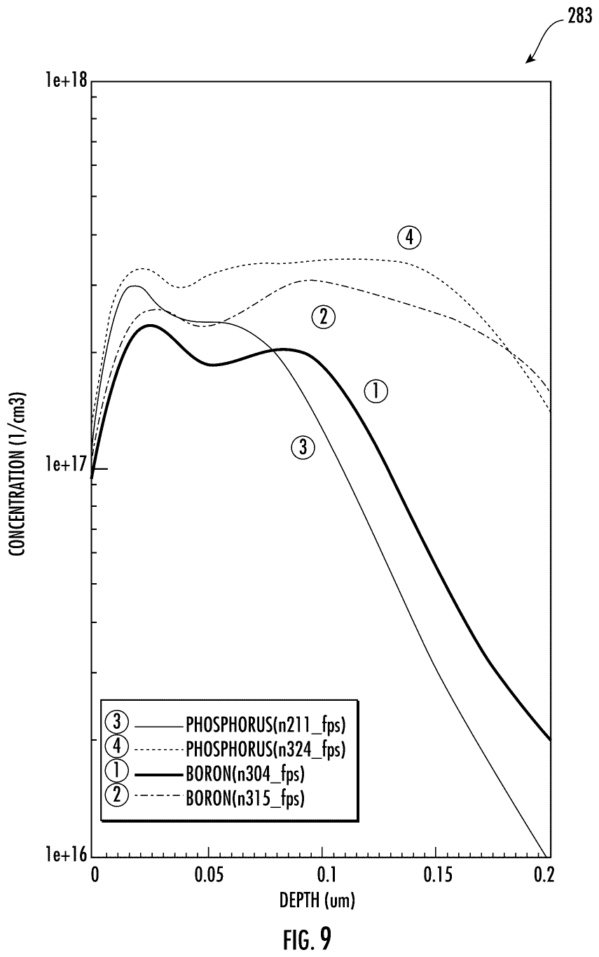

An example fabrication sequence is now described with reference to a SAW apparatus 280 including a transmitter 281, receiver 282, and SAW device 250 (FIG. 8), with simulated doping profiles shown in the graph 283 of FIG. 9. The example process sequence is as follows:
1. MST layer epitaxial growth (100-200 nm)
2. P-layer lithography and implant
   (a) BF2 35 keV 8E11 0° tilt+B 25 keV 2E12 0° tilt for 100 nm film
   (b) BF2 35 keV 8E11 0° tilt+B 25 keV 2E12 0° tilt+B 45 keV 3E12 0° tilt for 200 nm film
3. N-layer lithography and implant
   (c) P 18 keV 8E11 0° tilt+P 60 keV 2E12 0° tilt for bulk (111)
   (d) P 18 keV 8E11 0° tilt+P 60 keV 2E12 0° tilt+P 120 keV 4E12 0° tilt for RFSOI (100)
4. RTA (1000 C 5 s)
5. Oxide CVD
6. Contact lithography and etch
7. Metal lithography and deposition (lift-off)

Although the present application has been described in the context of SAW device, the device 250 may also be configured for numerous other applications such as those described further in the above-noted U.S. Pub. No. 2007/0161138, including: pyroelectric sensors; piezoelectric materials for use in transformers and other devices such as vibrators; ultrasonic transducers; wave frequency filters; low-power piezo-transformers to backlight LCD displays; high-power transformers such as for battery chargers; power management devices in computers, high-intensity discharge headlights for cars, etc.; pyroelectric materials for use in temperature sensors and thermal imaging devices (e.g., vidicon sensors); and ferroelectric materials for use in non-volatile memories, etc.

Many modifications and other embodiments will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included.

1. A method for making an electronic device comprising:
forming a semiconductor region comprising a semiconductor layer and at least one non-semiconductor monolayer constrained within a crystal lattice of the semiconductor layer;
forming a plurality of spaced apart alternating N-type and P-type regions within the semiconductor region;
forming at least one electrode associated with the semiconductor region; and
poling the semiconductor region to align a net electrical dipole moment thereof using the plurality of spaced apart alternating N-type and P-type regions.

2. The method of claim 1 further comprising forming an insulator between the poled region and the at least one electrode.

3. The method of claim 1 wherein forming the at least one electrode comprises forming a pair spaced apart interdigitated transducers (IDTs) defining a Surface Acoustic Wave (SAW) device.

4. The method of claim 1 wherein the net electrical dipole moment comprises a permanent electrical dipole moment.

5. The method of claim 1 wherein the semiconductor region comprises intrinsic regions between adjacent N-type and P-type regions.

6. The method of claim 1 wherein each of the N-type and P-type regions has a dopant concentration of at least 1×10¹⁷/cm³.

7. The method of claim 1 wherein the semiconductor layer and at least one non-semiconductor monolayer therein comprises a plurality of stacked groups of layers, each group of layers comprising a plurality of stacked base semiconductor monolayers defining a base semiconductor portion, with a respective non-semiconductor monolayer constrained within a crystal lattice of adjacent base semiconductor portions.

8. The method of claim 7 wherein the stacked base semiconductor monolayers comprise silicon.

9. The method of claim 7 wherein the non-semiconductor monolayers comprise oxygen.

10. The method of claim 1 comprising forming radio frequency (RF) circuitry coupled to the at least one electrode.

11. A method for making a radio frequency (RF) device comprising:
forming a semiconductor region comprising a semiconductor layer and at least one non-semiconductor monolayer constrained within a crystal lattice of the semiconductor layer;
forming a plurality of spaced apart alternating N-type and P-type regions within the semiconductor region;
forming at least one electrode associated with the semiconductor region;
forming RF circuitry coupled to the at least one electrode; and
poling the semiconductor region to align a permanent net electrical dipole moment thereof using the plurality of spaced apart alternating N-type and P-type regions.

12. The method of claim 11 further comprising forming an insulator between the poled region and the at least one electrode.

13. The method of claim 11 wherein forming the at least one electrode comprises forming a pair spaced apart interdigitated transducers (IDTs) defining a Surface Acoustic Wave (SAW) device.

14. The method of claim 11 wherein the poled semiconductor region comprises intrinsic regions between adjacent N-type and P-type regions.

15. The method of claim 11 wherein each of the N-type and P-type regions has a dopant concentration of at least 1×10¹⁷/cm³.

16. The method of claim 11 wherein the semiconductor layer and at least one non-semiconductor monolayer therein comprises a plurality of stacked groups of layers, each group of layers comprising a plurality of stacked base semiconductor monolayers defining a base semiconductor portion, with a respective non-semiconductor monolayer constrained within a crystal lattice of adjacent base semiconductor portions.

17. The method of claim 16 wherein the stacked base semiconductor monolayers comprise silicon.

18. The method of claim 16 wherein the non-semiconductor monolayers comprise oxygen.

19. A method for making an electronic device comprising:
forming a semiconductor region comprising a silicon layer and at least one oxygen monolayer constrained within a crystal lattice of the silicon layer;
forming a plurality of spaced apart alternating N-type and P-type regions within the semiconductor region;
forming at least one electrode associated with the semiconductor region; and
poling the semiconductor region to align a net electrical dipole moment thereof using the plurality of spaced apart alternating N-type and P-type regions.

20. The method of claim 19 wherein forming the at least one electrode comprises forming a pair spaced apart interdigitated transducers (IDTs) defining a Surface Acoustic Wave (SAW) device.

21. The method of claim 19 wherein the net electrical dipole moment comprises a permanent electrical dipole moment.

22. The method of claim 19 wherein the poled semiconductor region comprises intrinsic regions between adjacent N-type and P-type regions.
